(19) United States
(12) Patent Application Publication
(10) Pub. No.: US 2005/0241802 A1
(43) Pub. Date: Nov. 3, 2005

(54) Liquid loop with flexible fan assembly

(75) Inventors: Christopher G. Malone, Loomis, CA (US); Glenn C. Simon, Auburn, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 10/835,957

(22) Filed: Apr. 29, 2004

(51) Int. Cl. H05K 7/20

(52) U.S. Cl. 165/80.4; 361/699

(57) ABSTRACT

An assembly includes a heat exchanger with a tube and a plurality of fins coupled to the tube, and a mount coupled to the heat exchanger capable of attaching a variable number and configuration of fans to the heat exchanger.

### BACKGROUND OF THE INVENTION

Electronic systems and equipment such as computer systems, network interfaces, storage systems, and telecommunications equipment are commonly enclosed within a chassis, cabinet or housing for support, physical security, and efficient usage of space. Electronic equipment contained within the enclosure generates a significant amount of heat. Thermal damage may occur to the electronic equipment unless the heat is removed.

As electronic components and subsystems evolve to increasing capability, performance, and higher power, while reducing size and form factor, efficient and cost-effective removal of excess heat is desired. Among available thermal management solutions, liquid cooling via cold plate technology offers high capacity for heat rejection and movement of heat from internal sources to external ambient air. Liquid cooling loop systems typically cycle pumped coolants continuously, conveying excess heat from heat-generating devices. The heat is dispersed into ambient air using a heat exchanger or other device.

### SUMMARY

In accordance with an embodiment of an electronic liquid cooling system, an assembly includes a heat exchanger with a tube and a plurality of fins coupled to the tube, and a mount coupled to the heat exchanger capable of attaching a variable number and configuration of fans to the heat exchanger.

### BRIEF DESCRIPTION OF THE DRAWINGS

Embodiments of the invention relating to both structure and method of operation, may best be understood by referring to the following description and accompanying drawings.

FIGS. 1A, 1B, and 1C are perspective pictorial diagrams illustrating various embodiments of electronic liquid cooling systems and assemblies that support redundant fan configurations.

FIG. 2 is a perspective pictorial diagram showing an embodiment of an electronic system that supports redundant fan arrangements and flexible cooling capabilities.

FIGS. 3A, 3B, 3C, 3D, 3E, and 3F are perspective pictorial diagrams that depict several schematic pictorial diagrams showing examples of heat exchangers having various sizes and shapes, and a capability to support redundant fan arrangements.

FIG. 4 is a schematic pictorial diagram illustrating an embodiment of a quick disconnect connector that can be used to couple a cold plate to tubing in a liquid cooling loop system.

### DETAILED DESCRIPTION

Compact electronic devices and systems, such as server architectures, may use a liquid loop cooling solution to accommodate increasing power and power density levels for microprocessors and associated electronics. Liquid loops can use a pump to drive cooling fluid through high pressure-drop channels of the colds plates attached to processors and other high-power components and along potentially long and narrow-diameter tube completing the loop between the cold plate, condenser, and pump. Heat is removed from the loop by forced-air convection at the condenser.

A disclosed electronic liquid cooling system includes a redundant fan configuration to increase reliability, thereby eliminating the weakness of a single point-of-failure implementation.

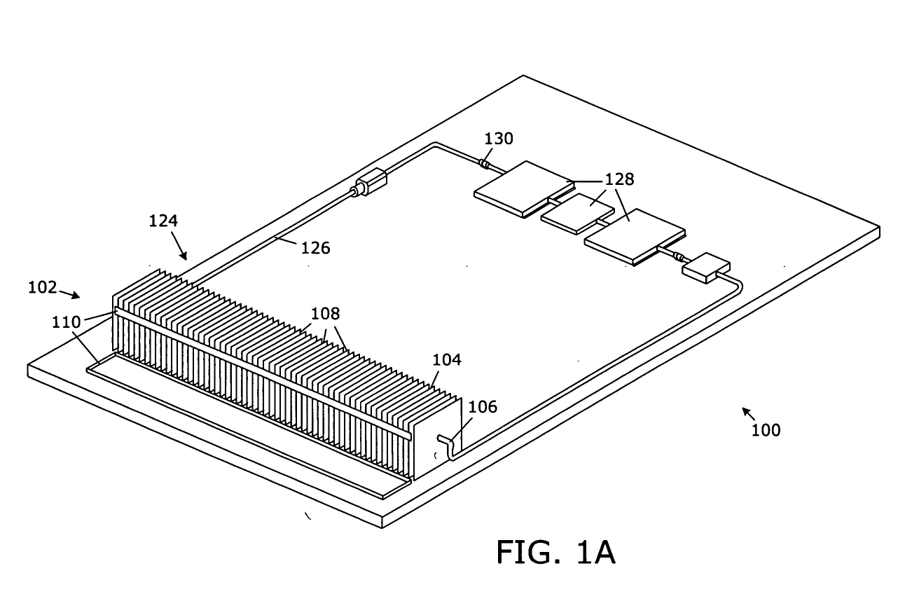

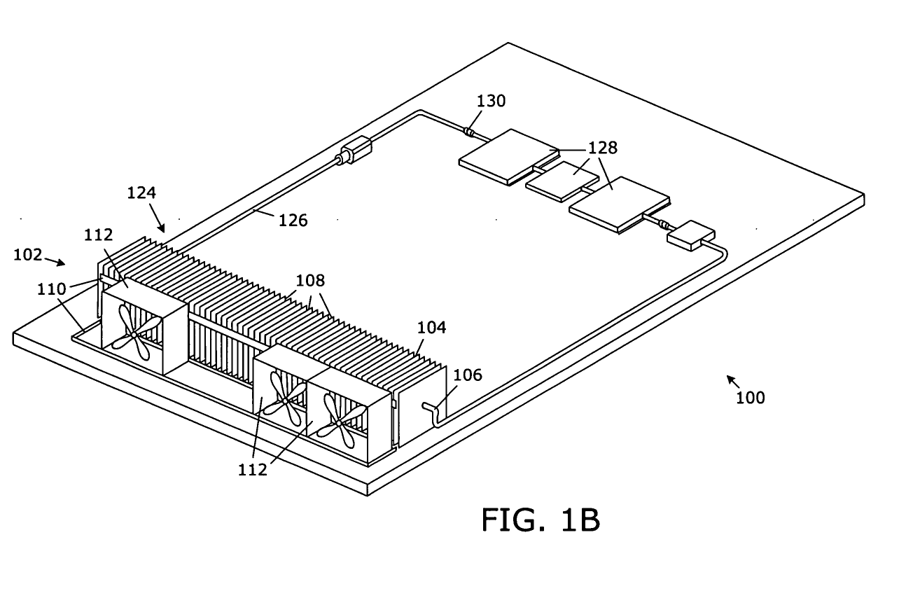

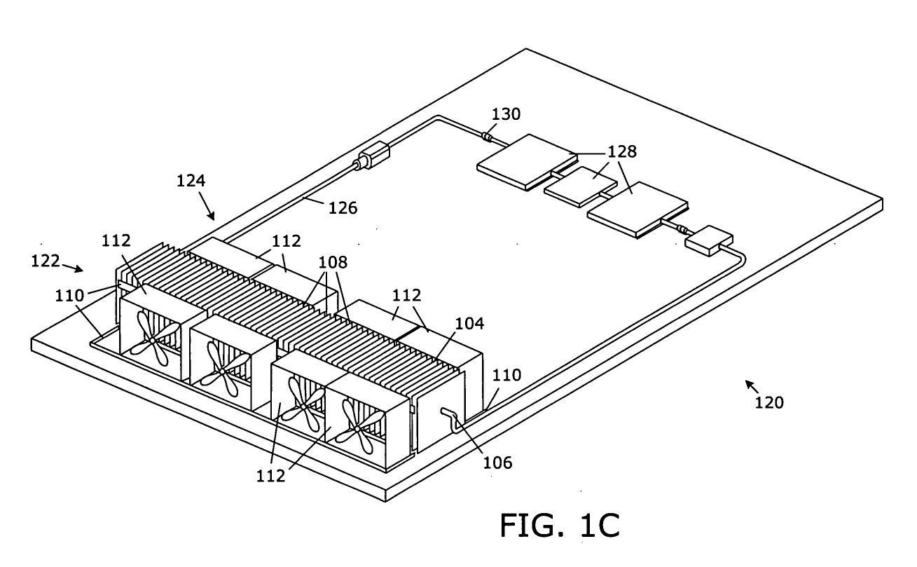

Referring to FIG. 1A, a perspective pictorial diagram illustrates an embodiment of an assembly 102 for usage in an electronic liquid cooling system 100. The assembly 102 includes a heat exchanger 104 comprising a tube 106 and a plurality of fins 108 coupled to the tube 106. The assembly 102 further includes a mount 110 coupled to the heat exchanger 104 that can attach a variable number and configuration of fans to the heat exchanger 104. Fin size and placement can be selected to obtain a desired flow rate and heat transfer performance.

Referring to FIG. 1B, a perspective pictorial diagram shows the embodiment of the assembly 102 including a plurality of fans 112 attached to the mount 110. The number of fans is selected to be at least one higher than a minimum to meet system cooling specifications. The mount 110 accommodates a sufficiently large number of fans 112 to enable expansion of system thermal generation.

Referring to FIG. 1C, a perspective pictorial diagram depicts an embodiment of an assembly 122 for an electronic liquid cooling system 120 that includes mounts 110 coupled to opposing sides of the heat exchanger 104 to enable attachment of fans 112 to generate an upstream airflow into the heat exchanger 104 and a downstream airflow pulled from the heat exchanger 104.

In the various embodiments of the assembly 102, 122, a sufficiently large number of fans 112 can be mounted to the heat exchanger 104 to exceed system cooling specifications, enabling less expensive and less reliable fans to be used while retaining high reliability.

Also referring to FIGS. 1A, 1B, and 1C, an electronic liquid cooling system 124 includes a tubing 126 enclosing an interior bore or lumen within which a cooling fluid can circulate, a heat exchanger 104 coupled to the tubing 126 and including a tube 106 and multiple fins 108 coupled to the tube 106. The electronic liquid cooling system 124 further includes a mount 110 coupled to the heat exchanger 104 that can attach a variable number and configuration of fans 112 to the heat exchanger 104.

The electronic liquid cooling system 124 further includes a plurality of cold plates 128 coupled to the tubing 126 and capable of addition and removal via quick disconnect connectors 130. A typical example of a cold plate 128 is a flat metal plate with a series of channels on one or both sides. A length of serpentine tubing can be secured within the channels to contain the liquid coolant flows. Fittings at the inlet and outlet of the tubing connect to the tubing 126. Common tubing materials are copper and stainless steel. Components may be mounted on one or both sides of a cold plate 128.

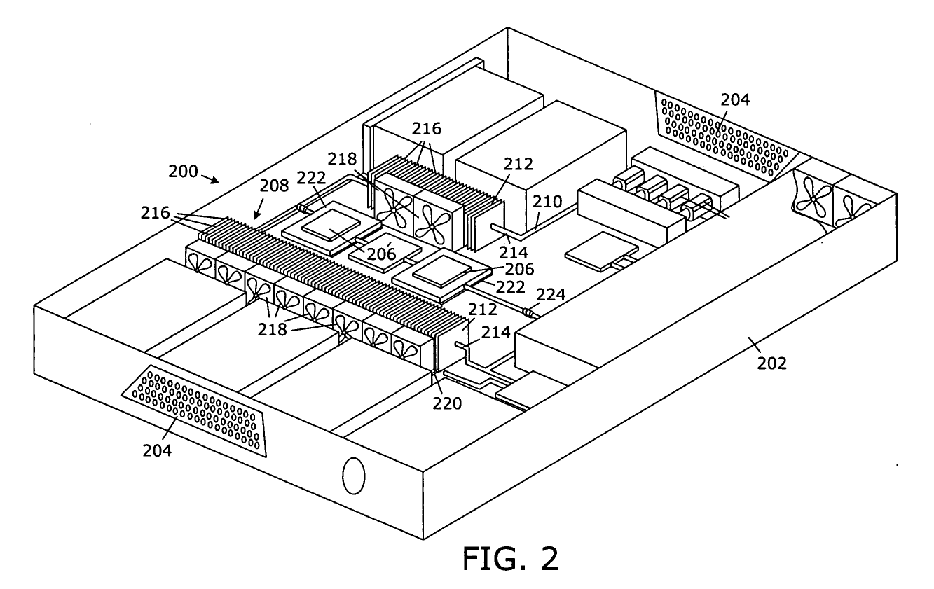

Referring to FIG. 2, a perspective pictorial diagram illustrates an embodiment of an electronic system 200 including a chassis 202 including airflow inlet and outlet vents 204, a plurality of components 206 including heat-generating components mounted within the chassis 202, and an electronic liquid cooling system 208. The electronic liquid cooling system 208 includes a tubing 210 enclosing an interior bore or lumen within which a cooling fluid can circulate, a heat exchanger 212 coupled to the tubing and further including a tube 214 and a plurality of fins 216 coupled to the tube 214. The electronic liquid cooling system 208 further includes a plurality of fans 218 associated with the heat exchanger 212 in a number at least one higher than a minimum to meet system cooling specifications.

The number and arrangement of heat sources, for example heat-generating components 206, may be varied in different electronic system configurations. The flexible electronic liquid cooling system 208 enables variation of the number of cooling fans 218 for condenser or heat exchanger cooling. In the illustrative system, a varying number of fans 218 can be allocated in association with a particular heat exchanger 212.

The electronic liquid cooling system 208 may further include one or more mounts 220 coupled to the heat exchanger 212 that can attach a variable number and configuration of fans 218 to the heat exchanger 212. One or more cold plates 222 can be coupled to the tubing 210 to facilitate addition and removal via quick disconnect connectors 224.

The illustrative electronic system 200 and electronic liquid cooling system 208 can be arranged with multiple various fan configurations to attain a lower cost and/or enable upgrading to liquid loop cooling capabilities. The electronic system 200 and electronic liquid cooling system 208 can be designed by determining thermal conditions within the electronic system 200. Airflow patterns within the chassis 202 may be determined according to sizes and positioning of devices and components 206 and other internal obstructions. Coolant flow patterns within the tubing 210 is also determined including analysis of sizing of individual components 206 and cold plates 222 to enable a selected flow to be delivered to cold plates 222 and any heat sinks onto which electronic components 206 may be mounted. Analysis of the liquid loop may also take into consideration the arrangements of the tubing 210 and tubes 214 in the heat exchangers 212 as well as impact on flow of any junctions or quick disconnects 224 coupled to the tubing 210. The thermal conditions also vary depending on heat generated by particular components 206 and transfer to cooling plates 222.

The method for electronic liquid cooling system design further includes configuring the liquid loop cooling system 208 with one or more heat exchangers 212 associated with a plurality of fans 218. The number and positioning of the fans 218 is selected to be at least one higher than a minimum to meet cooling specifications based on the thermal conditions.

In some applications, the liquid loop cooling system 208 may be populated with multiple lower-cost, lower-reliability fans in a number sufficiently high that more than one fan may fail while maintaining cooling system integrity.

The electronic liquid cooling system 208 may be designed for redundancy, for example for N+1 fans when N fans are sufficient to meet cooling specifications. Customers or those configuring systems on the basis of minimum cost and who are not willing to pay extra for redundancy may arrange a system with redundant fans eliminated, resulting in a lower system cost. A customer can purchase a system with N cooling fans for a low entry price point.

The flexible fan configuration enables an initial design of the liquid loop cooling solution that is oversized. Fewer fans or lower performance fans can be initially installed to lower costs while meeting initial heat loads. Subsequent system upgrades, for example to higher power processors, are accommodated by adding fans or replacing initially-installed low-cost fans with faster, higher-performance fans. The flexible system thus enables low initial cost and supports flexible upgrading that can substantially improve cooling performing without change to installed cold plates 222.

The oversized liquid loop can support a wide range of numbers of cold plates 222 and heat sources, and support a high degree of modification flexibility through usage of quick disconnects, facilitating removal and addition of heat sources and cold plates.

In other applications, the electronic system 200 and/or electronic liquid cooling system 208 may be designed to accommodate many small, low-cost fans with lower reliability in such a way that more than one fan may fail without impacting integrity of the cooling solution. The configuration may enable a lower overall material cost relative to the use of larger, more reliable and costly fans. Flexibility of heat exchanger geometry may be exploited to enable additional fan arrangements.

The flexible fan arrangement enables a liquid loop configuration with additional cooling capacity than is necessary for a first release of a particular electronic system, such as a server. Fan slots adjacent the heat exchanger 212 may not be fully loaded in a first release to enable a lower initial cost. Upgrades to higher power devices and components, such as higher performance processors, are accommodated by adding fans to the open slots or replacing existing fans with higher performance models. The flexibility enabled by the disclosed arrangement of compact heat exchangers, liquid cooling, and variable arrangement of fans may be difficult to attain in traditional air-cooled heat sink designs.

As an electronic system 200 is upgraded by modifying the electronic component combination, the configuration of fans may also be modified based on changed thermal conditions due to the electronic component combination modification.

The illustrative heat exchanger 212 and tubing 210 can be configured for usage in multiple platforms and with multiple heating sources. Varying numbers of heat sources can be added or removed using quick disconnects 224. Varying cooling criteria and form factors are accommodated through usage of a wide range of numbers and sizes of cooling fans 218. The basic components of the electronic liquid cooling system 208 can be arranged in various configurations and in differing numbers, sizes, and performance characteristics across multiple platforms, resulting in lower manufacturing costs through larger volumes, fewer parts in the field, and the like.

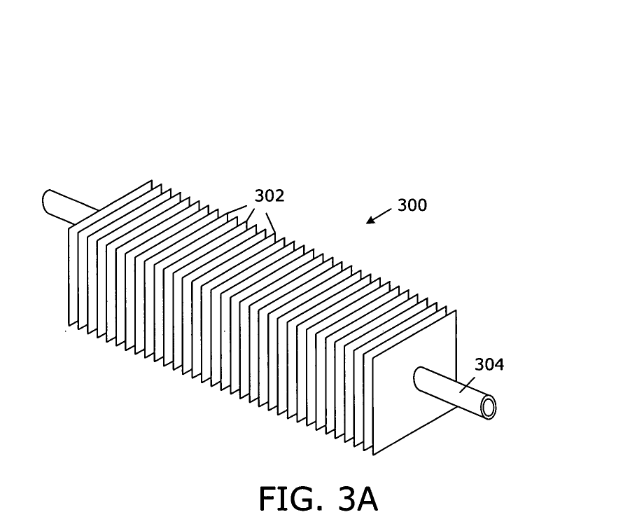

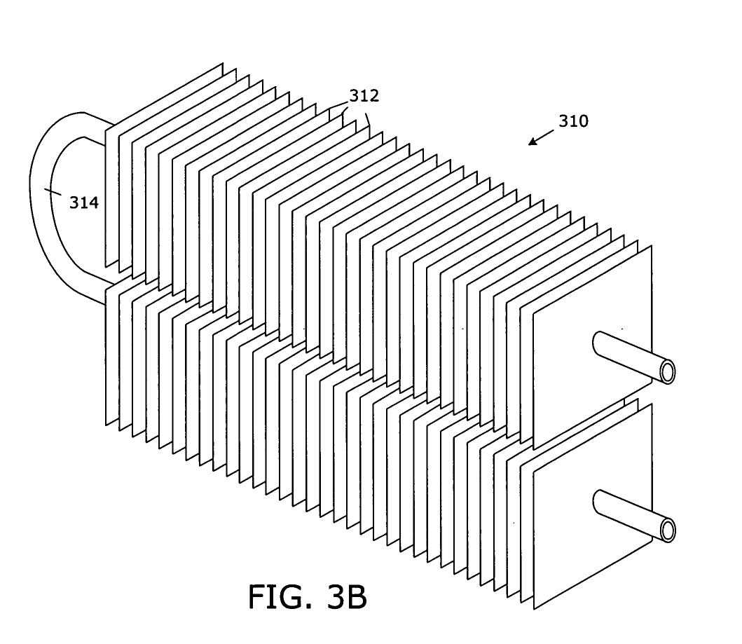

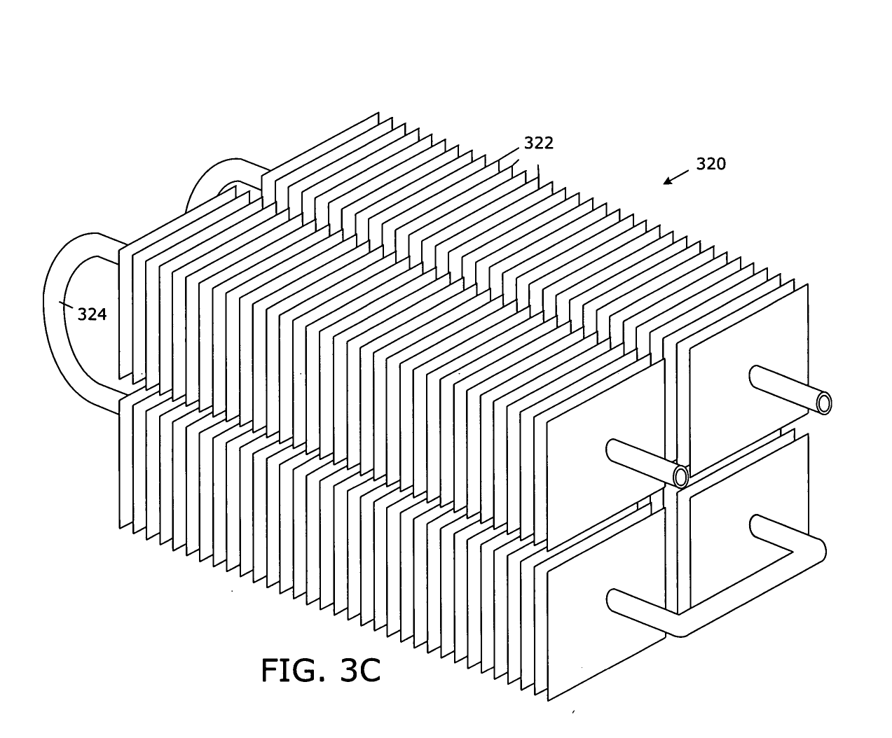

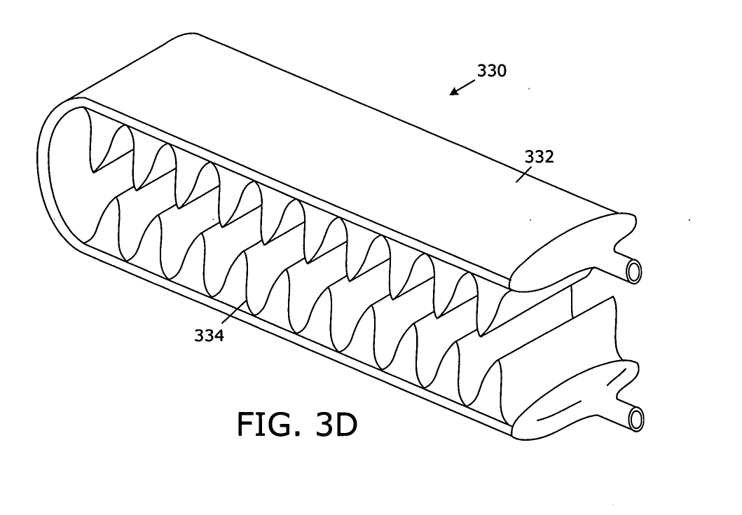

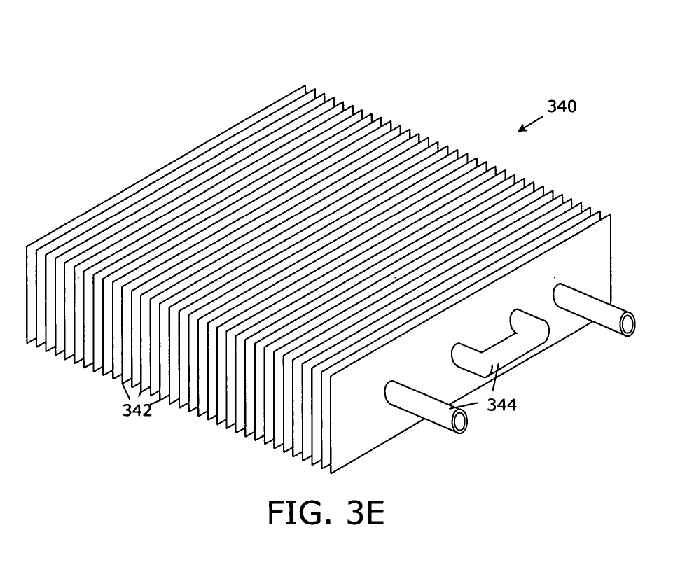

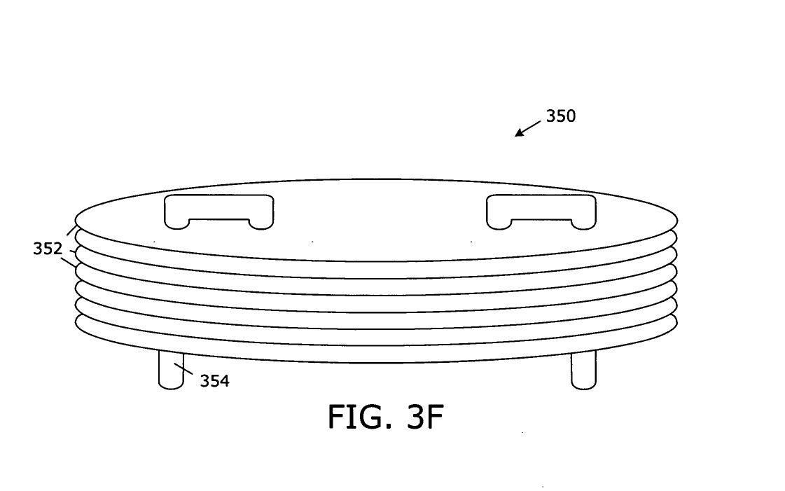

A condenser is typically a compact heat exchanger 212 constructed of the fins 216 attached to the tube 214 containing the cooling fluid. The tube 214 may pass through the fin bank 216 many times and in various orientations to attain optimized cooling performance. FIGS. 3A, 3B, 3C, 3D, and 3E, are perspective pictorial diagrams that depict several schematic pictorial diagrams showing examples of heat exchangers having various sizes and shapes. FIG. 3A depicts a single-pass liquid-to-air heat exchanger 300 constructed as a stack of closely-spaced plates or fins 302 attached to a tubing or tube segment 304 having a longitudinal axis and a circular cross-section. In some embodiments, the closely-stacked plates 302 may be arranged substantially perpendicular to the longitudinal axis of the tube segment 304. The single-pass heat exchanger 300 can be relatively long and thin for positioning within long and narrow spaces between components and devices within a chassis or housing. For example, the single-pass liquid-to-air heat exchanger 300 may be inserted in a space adjacent to one or more input/output devices.

FIG. 3B illustrates an embodiment of a dual-pass liquid-to-air heat exchanger 310 in which more heat can be transferred to the air than in a single-pass exchanger. The dual-pass exchanger 310 may be arranged to fit available space within a chassis. For example, for long, narrow trenches between components and devices, the dual-pass exchanger 310 may be inserted into a trench with parallel segments of the tubing 314 and fins 312 stacked vertically. In other examples, wider spaces between components and devices may enable the parallel segments of the dual-pass heat exchanger 310 to be stacked horizontally, increasing heat removal for low-lying components such as processors.

FIG. 3C shows an embodiment of a multiple-pass liquid-to-air heat exchanger 320, more specifically a quad-pass exchanger although any number of tubing segments 324 may be used, depending on available spacing and form factor considerations. The tube 324 may pass through a fin bank 322 multiple times and in various orientations to attain improved or optimized cooling performance. The multiple-pass heat exchanger 320 may be used in systems with relative large spaces between components and devices to even further supply a cooling capability. In the illustrative embodiment, fins 322 coupled to the various tubing segments 324 are separated by a gap to reduce or eliminate reheating of the cooling liquid by conduction of heat along the fins 322.

FIG. 3D illustrates an embodiment of a dual-pass liquid-to-air heat exchanger 330 is in the form of a flattened tube 332 for carrying a cooling liquid with folded fins 334 soldered or braised to the tube 332. In the illustrative embodiment, two separate sets of folded fins are used, one attached to a first tube segment and a second attached to a second tube segment. The flattened-tube heat exchanger 330 enables a large variety of arrangements, sizes, and configurations, simply by selecting the sizes and topology of folded fins 334 and tube 332.

FIG. 3E illustrates and example of a relatively short and flat multiple-pass heat exchanger 340 with a plurality of tubing segments 344 passing through a single stack of fins 342. The heat exchanger 340 may be used in a relatively wide and long, but low height space in a system. In other examples, the heat exchanger 340 may be positioned overlying a group of low-lying components, such as multiple components such as processors and memory, on a printed circuit card.

FIG. 3F illustrates an example of a single or multiple-pass heat exchanger 350 with fins or plates 352 in the form of a plurality of elliptical or circular disks with one or more tube segments 354 passing through the fins or places 352. In some examples, the elliptical or circular heat exchanger 350 may also be used in low height spaces.

Multiple fan configurations are associated with the different heat exchanger configurations to enable flexible cooling capabilities.

In a compact server, cooling air is driven across a heat exchanger using common tube-axial or blower fans. Liquid loops enable a high degree of flexibility regarding dimensions of the heat exchanger. The heat exchangers may be sized to fit the width of a single fan or span the width of several fans arranged side-by-side. Heat exchanger designs that accommodate multiple fans may enable redundant fan cooling solutions. For example, one of the fans may fail and the remaining fans supply sufficient cooling air flow to meet component temperature requirements.

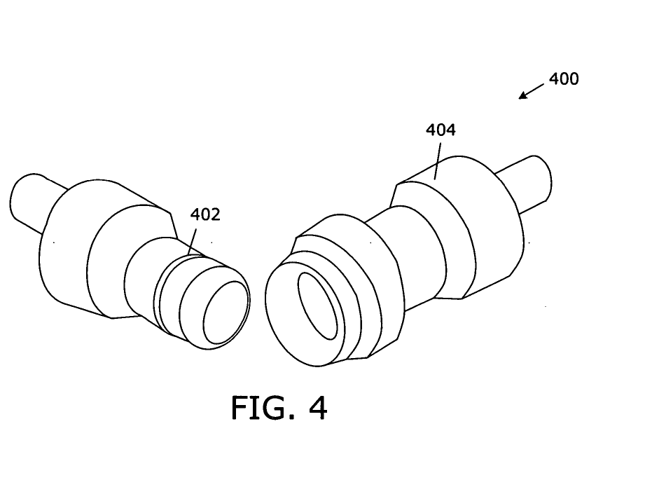

Referring to FIG. 4, a schematic pictorial diagram illustrates an example of a quick disconnect connector 400 that can be used to couple a cold plate to tubing in a liquid cooling loop system. The illustrative quick disconnect connector 400 includes a nonspill male insert 402 and a female body coupler 404. The connector 400 can include automatic or integral shut-off valves to support various shutoff characteristics including single-sided, double-sided, and nonspill characteristics. The connector 400 can be coupled to tubing via various known techniques including hose barb, compression fittings, push-to-connect and the like.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims. For example, although particular geometries of the redundant fan and heat exchanger arrangements are shown, other arrangements are possible including additional multiple-pass arrangements in which additional fans, heat exchanger geometries, and heat exchanger segments are added. Also, particular electronic system embodiments are illustrated, for example a computer server. In other embodiments, the external heat exchanger can be employed in other types of electronic systems such as communication systems, storage systems, entertainment systems, and the like.

1. An assembly for an electronic liquid cooling system comprising:
a heat exchanger comprising a tube and a plurality of fins coupled to the tube; and
a mount coupled to the heat exchanger capable of attaching a variable number and configuration of fans to the heat exchanger.

2. The assembly according to claim 1 further comprising:
a plurality of fans attached to the mount, the number of fans in the plurality of fans being at least one higher than a minimum to meet system cooling specifications.

3. The assembly according to claim 1 further comprising:
mounts coupled to opposing sides of the heat exchanger for attaching fans to generate an upstream airflow into the heat exchanger and a downstream airflow pulled from the heat exchanger.

4. The assembly according to claim 1 further comprising:
a sufficiently large number of fans mounted to the heat exchanger to exceed system cooling specifications so that less expensive and less reliable fans may be used with higher reliability.

5. The assembly according to claim 1 further comprising:
the mount accommodates a sufficiently large number of fans to enable expansion of system thermal generation.

6. A electronic liquid cooling system comprising:
a tubing enclosing an interior bore or lumen within which a cooling fluid can circulate;
a heat exchanger coupled to the tubing and comprising a tube and a plurality of fins coupled to the tube; and
a mount coupled to the heat exchanger capable of attaching a variable number and configuration of fans to the heat exchanger.

7. The system according to claim 6 further comprising:
a plurality of cold plates coupled to the tubing and capable of addition and removal via quick disconnect connectors.

8. The system according to claim 6 further comprising:
a plurality of fans attached to the mount, the number of fans in the plurality of fans being at least one higher than a minimum to meet system cooling specifications.

9. The system according to claim 6 further comprising:
mounts coupled to opposing sides of the heat exchanger for attaching fans to generate an upstream airflow into the heat exchanger and a downstream airflow pulled from the heat exchanger.

10. The system according to claim 6 further comprising:
a sufficiently large number of fans mounted to the heat exchanger to exceed system cooling specifications so that less expensive and less reliable fans may be used with higher reliability.

11. The system according to claim 6 further comprising:
the mount accommodates a sufficiently large number of fans to enable expansion of system thermal generation.

12. An electronic system comprising:
a chassis including airflow inlet and outlet vents;
a plurality of components including heat-generating components mounted within the chassis; and
an electronic liquid cooling system comprising:
a tubing enclosing an interior bore or lumen within which a cooling fluid can circulate;
a heat exchanger coupled to the tubing and comprising a tube and a plurality of fins coupled to the tube; and
a plurality of fans associated with the heat exchanger in a number at least one higher than a minimum to meet system cooling specifications.

13. The system according to claim 12 further comprising:
a mount coupled to the heat exchanger capable of attaching a variable number and configuration of fans to the heat exchanger.

14. The system according to claim 12 further comprising:
one or more cold plates coupled to the tubing and capable of addition and removal via quick disconnect connectors.

15. The system according to claim 12 wherein:
mounts coupled to opposing sides of the heat exchanger for attaching fans to generate an upstream airflow into the heat exchanger and a downstream airflow pulled from the heat exchanger.

16. The system according to claim 12 wherein:
a sufficiently large number of fans mounted to the heat exchanger to exceed system cooling specifications so that less expensive and less reliable fans may be used with higher reliability.

17. The system according to claim 12 wherein:
the number of fans is sufficient to enable expansion of system thermal generation.

18. A method of cooling an electronic system comprising:
determining thermal conditions within the electronic system;
configuring a liquid loop cooling system with a heat exchanger associated with a plurality of fans, the number and positioning of the fans being at least one higher than a minimum to meet cooling specifications based on the thermal conditions.

19. The method according to claim 18 further comprising:
populating the liquid loop cooling system with multiple lower-cost, lower-reliability fans in a number sufficiently high that more than one fan may fail while maintaining cooling system integrity.

20. The method according to claim 18 further comprising:
modifying an electronic component combination within the electronic system; and
modifying the configuration of fans based on changed thermal conditions due to the electronic component combination modification.
